(19) United States
(12) Patent Application Publication
(10) Pub. No.: US 2026/0214918 A1
(43) Pub. Date: Jul. 23, 2026

(54) INDUCTOR MODULE, POWER STAGE MODULE AND METHODS OF PRODUCING THE SAME

(71) Applicant: Infineon Technologies Austria AG, Villach (AT)

(72) Inventors: Surendhar Somasundaram, Santa Clara, CA (US); Angela Kessler, Sinzing (DE); Paul Yeaman, Pelham, NH (US); Paul Westmarland, Surrey (GB); Anil Jeswani, Acton, MA (US)

(21) Appl. No.: 19/033,651

(22) Filed: Jan. 22, 2025

(51) Int. Cl. H10D 1/20; H01F 27/24; H01F 41/02; H01L 23/373; H01L 25/18; H10D 1/00

(52) U.S. Cl. CPC H10D 1/20; H01F 27/24; H01F 41/0206; H10D 1/01; H10W 90/00; H10W 40/258

(57) ABSTRACT

An inductor module includes: a magnetic core having a first main surface, a second main surface opposite the first main surface, and a plurality of side faces extending between the first and the second main surfaces; an inductor extending from the first main surface to the second main surface through the magnetic core; and a metallic body adjoining the first main surface, the second main surface and at least one of the side faces of the magnetic core. The metallic body and the inductor are electrically isolated from one another. Also described are a power stage module that includes the inductor module and methods of producing the inductor module and the power stage module.

### BACKGROUND

Power stage modules are widely used in power electronics applications that demand high power density and low switching losses, such as server power supplies and AI (artificial intelligence) computing. A typical power stage module includes a half bridge formed by one or more high-side side power MOSFET (metal-oxide-semiconductor field-effect transistor) dies (chips) and one or more low-side power MOSFET dies, and a driver for switching the power MOSFET dies. Parasitics and power losses may be reduced by mounting the power stage module close to the system processor. This typically requires a package design with a small outline but with the capability of switching high current, which means large die sizes. The area of the power stage module may be further reduced by vertically stacking the passive components such as inductors, capacitors, etc. above the power dies on a carrier such as a PCB (printed circuit board). The target is to create a power stage module with maximized current density A/mm², but also a low Rth (thermal resistance) junction to the top and bottom of the module. Conventional power stage modules have adequate power density but offer limited Rth junction performance.

Thus, there is a need for an improved power stage module design.

### SUMMARY

According to an embodiment of an inductor module, the inductor module comprises: a magnetic core having a first main surface, a second main surface opposite the first main surface, and a plurality of side faces extending between the first and the second main surfaces; an inductor extending from the first main surface to the second main surface through the magnetic core; and a metallic body adjoining the first main surface, the second main surface and at least one of the side faces of the magnetic core, wherein the metallic body and the inductor are electrically isolated from one another.

According to an embodiment of a method of producing an inductor module, the method comprises: partly embedding an inductor in a magnetic core having a first main surface, a second main surface opposite the first main surface, and a plurality of side faces extending between the first and the second main surfaces, such that the inductor extends from the first main surface to the second main surface through the magnetic core; and fixing a metallic body to the magnetic core, the metallic body adjoining the first main surface, the second main surface and at least one of the side faces of the magnetic core, wherein the metallic body and the inductor are electrically isolated from one another.

According to an embodiment of a power stage module, the power stage module comprises: a substrate; a plurality of semiconductor dies attached to or embedded in the substrate; and an inductor module mounted to a first side of the substrate above the semiconductor dies, wherein the inductor module comprises: a magnetic core having a first main surface that faces the substrate, a second main surface opposite the first main surface, and a plurality of side faces extending between the first and the second main surfaces; an inductor partly embedded in the magnetic core and electrically connecting a switch node pad at the first side of the substrate to an output pad at the first side of the substrate; and a metallic body adjoining the first main surface, the second main surface and at least one of the side faces of the magnetic core, the metallic body being connected to a heat dissipation pad at the first side of the substrate, wherein the heat dissipation pad is grounded, floating or at any voltage potential but output voltage potential.

According to an embodiment of a method of producing a power stage module, the method comprises: attaching a plurality of semiconductor dies to a substrate or embedding the plurality of semiconductor dies in the substrate; and mounting an inductor module to a first side of the substrate above the semiconductor dies, the inductor module comprising: a magnetic core having a first main surface that faces the substrate, a second main surface opposite the first main surface, and a plurality of side faces extending between the first and the second main surfaces; an inductor partly embedded in the magnetic core and electrically connecting a switch node pad at the first side of the substrate to an output pad at the first side of the substrate; and a metallic body adjoining the first main surface, the second main surface and at least one of the side faces of the magnetic core, the metallic body being connected to a heat dissipation pad at the first side of the substrate, wherein the heat dissipation pad is grounded, floating or at any voltage potential but output voltage potential.

Those skilled in the art will recognize additional features and advantages upon reading the following detailed description, and upon viewing the accompanying drawings.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a top perspective view of an inductor module.

FIG. 2 illustrates a cross-sectional view of the inductor module along the line labelled A-A′ in FIG. 1.

FIG. 3 illustrates perspective views of different layers of a substrate of a power stage module to which the inductor module is mounted.

FIGS. 4 through 18 illustrate top perspective views of the inductor module, according to additional embodiments.

FIG. 19 illustrates a side view of the inductor module and a side perspective view of a metallic body included in the inductor module, according to another embodiment.

FIGS. 20A and 20B illustrates opposing side perspective views of the metallic body included in the inductor module, according to another embodiment.

FIG. 21A shows a side perspective view of the inductor module with the metallic body cap placed on an end of the magnetic core.

FIG. 21B shows a corresponding side view of the inductor module with the metallic body cap in place.

### DETAILED DESCRIPTION

The embodiments described herein provide an inductor module for power stage modules, the inductor module enabling optimal power density and enhanced Rth (thermal resistance) junction performance for the power stage module. Thermal resistance at the topside of the power stage module is enhanced by including an additional metallic body in the inductor module that is used for heat transfer only. The metallic body adjoins the magnetic core of the inductor module but is electrically isolated from the current-carrying inductor and therefore does not carry any of the current being switched by the power stage module. The switched current is instead carried by the inductor of the inductor module, which is partly embedded in the magnetic core. The metallic body, which is separate from the inductor, transfers heat dissipated by the semiconductor dies included in the power stage module, out of the power stage module to the topside for an improved Rth junction at the topside of the power stage module. The metallic body may adjoin one or more side faces of the magnetic core and may have various shapes, configurations, and surface features.

Described next, with reference to the figures, are exemplary embodiments of the inductor module, a power stage module that includes the inductor module, and methods of producing the inductor module and the power stage module.

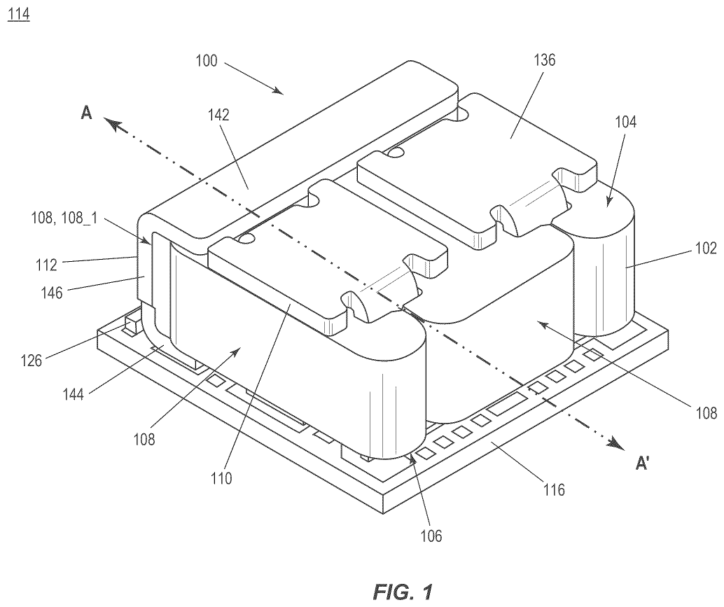

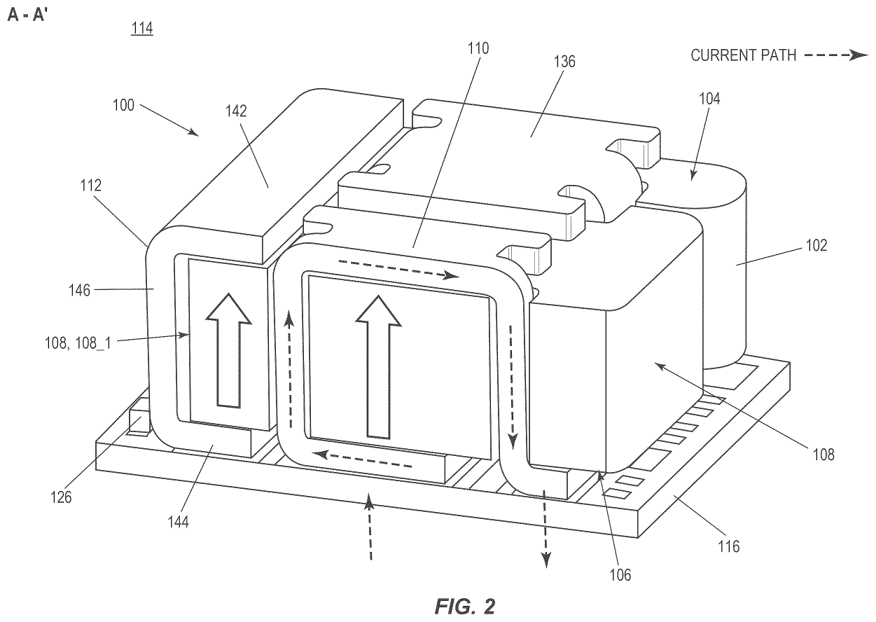

FIG. 1 illustrates a top perspective view of an inductor module 100. FIG. 2 illustrates a cross-sectional view of the inductor module 100 along the line labelled A-A′ in FIG. 1. The inductor module 100 includes a magnetic core 102 having a first main surface 104, a second main surface 106 opposite the first main surface 104, and a plurality of side faces 108 extending between the first and the second main surfaces 104, 106. An inductor 110 extends from the first main surface 104 to the second main surface 106 through the magnetic core 102. The inductor 110 may comprise Cu (copper) or any other metal or metal alloy that has high values of thermal conductivity and electrical conduction for good thermal and electrical performance. The inductor 110 may be shaped as a rod, winding, bent piece, etc.

The inductor module 100 also includes a metallic body 112 that adjoins the first main surface 104, the second main surface 106 and at least one of the side faces 108 of the magnetic core 102. The metallic body 112 and the inductor 110 are electrically isolated from one another. The inductor module 100 may be produced by partly embedding the inductor 110 in the magnetic core 102 and fixing the metallic body 112 to the magnetic core 102. For example, the magnetic core 102 may include two (2) or more pieces that form an opening through the core 102 when the pieces are joined together. The pieces of the magnetic core 102 may be joined together around the inductor 110 such that the inductor 110 extends from the first main surface 104 to the second main surface 106 through the magnetic core 102. The metallic body 112 may be fixed to one or more side faces 108 of the magnetic core 102 by gluing, soldering, taping, etc.

The inductor 110 that is partly embedded in the magnetic core 102 is configured to carry a current switched by a power stage module 114 that includes the inductor module 100, whereas the metallic body 112 is configured to transfer heat dissipated by the power stage module 114 but does not carry any of the current being switched. The metallic body 112 may comprise Cu (copper) or any other metal or metal alloy that has high values of thermal conductivity and electrical conduction for good thermal performance. The metallic body 112 and the inductor 110 may comprise the same or different metallic material, and may be formed by the same or different process.

For example, the metallic body 112 and the inductor 110 may be formed by sheet metal processing, e.g., stamping, etching, bending, etc. a metallic sheet. In FIGS. 1 and 2, the metallic body 112 is C-shaped and adjoins a single side face 108 of the magnetic core 102. The surface area of the metallic body 112 may be increased to further enhance thermal performance, e.g., by using other processes such as metal injection molding or metal 3D printing. Surface features such as ridges, fins, etc. can be added to the metallic body 112. The metallic body 112 can be chemically treated to form surface features. Channels may be formed within the metallic body 112 to enable liquid cooling. The metallic body 112 may have different thicknesses to further enhance thermal performance. In each case, the metallic body 112 is well-suited for use in high current density power stage modules, to transfer heat to the module topside for an improved Rth junction to the topside.

The power stage module 114 may form part of a power electronics circuit for use in various power applications such as a DC/AC inverter, a DC/DC converter, an AC/DC converter, a DC/AC converter, an AC/AC converter, a multi-phase inverter, an H-bridge, motor drive, etc. For example, the power stage module 114 may be used in applications such as server power supplies, AI computing, etc.

The pathway for the switched current supported by the power stage module 114 is indicated by dashed lines in FIG. 2. The metallic body 112 does not carry any of the switched current. Both the metallic body 112 and the inductor 110 transfer heat from a substrate 116 vertically stacked below the inductor module 100 to the topside of the power stage module 114, as indicated by the solid arrows shown in FIG. 2. Accordingly, the metallic body 112 enhances the thermal performance of the power stage module 114. In each case, production of the power stage module 114 may further include mounting the inductor module 100 to a first (e.g., front) side of the substrate 116. The mounting of the inductor module 100 may include fastening the inductor 110 and the metallic body 112 of the inductor module 100 to respective metallic pads of the substrate 116. For example, the substrate 116 may be a PCB and the inductor module 100 may be soldered to the PCB. Other types of substrates may be used, e.g., a DCB (direct copper bonded), AMB (aluminum metal brazed), IMS (insulated metal substrate), etc.

In another embodiment, the inductor module 100 with the inductor 110 and the integrated metallic body 112 may be attached to or integrated on top of a leadframe based power module. According to this embodiment, the power stage dies 118 may be soldered to the leadframe at the bottom, i.e., at the opposite side as the inductor module 100, instead of being embedded in a substrate 116.

In another embodiment, the inductor module 100 with the inductor 110 and the integrated metallic body 112 may be embedded or over-molded in a substrate/leadframe along with the power stage dies 118, forming a larger integrated module.

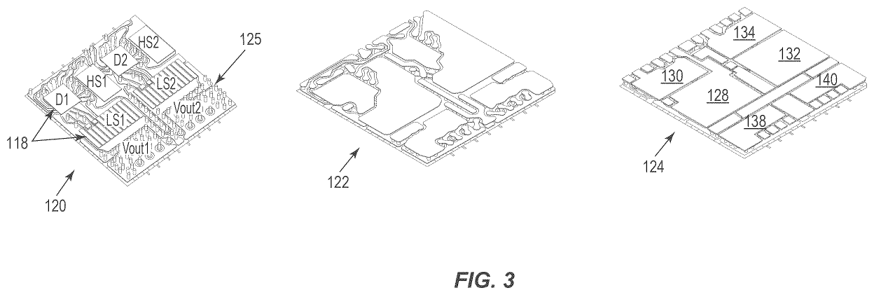

FIG. 3 illustrates perspective views of different layers of the substrate 116 included in the power stage module 114. Semiconductor dies 118 that enable current switching are embedded in the substrate 116 of the power stage module 114 in FIGS. 1 through 3. Instead, some or all of the semiconductor dies 118 may be attached to the top and/or bottom side of the substrate 116. Accordingly, the substrate/die arrangement may be formed by attaching some or all of the semiconductor dies 118 to the substrate 116 and/or by embedding some or all of the semiconductor dies 118 in the substrate 116.

In FIG. 3, the leftmost illustration shows a layer 120 of the substrate 116 that includes the semiconductor dies 118. The middle illustration in FIG. 3 shows a layer 122 of the substrate 116 above the semiconductor dies 118 and that provides electrical redistribution. The rightmost illustration in FIG. 3 shows an uppermost layer 124 of the substrate 116 and at which electrical connections are made to the substrate 116. The inductor module 100 is mounted to the uppermost layer 124 of the substrate 116, e.g., as shown in FIGS. 1 and 2. Additional components such as capacitors 126 may be mounted to the uppermost layer 124 of the substrate 116, e.g., also as shown in FIGS. 1 and 2 and/or to the bottom side of the substrate 116. Internal electrical connections between the semiconductor dies 118 may be implemented by the layers 120, 122, 124 and electrically conductive vias of the substrate 116. For example, the substrate 116 may be a multi-layer PCB.

The electronic components 100, 118, 126 included in the power stage module 114 form a power converter circuit such as a half bridge, full bridge, etc. For example, the semiconductor dies 118 embedded in or attached to the substrate 116 may include a high-side power transistor die HS1 electrically connected between an input voltage potential Vin of the power stage module 114 and a switch node pad 128 included in the uppermost layer 124 of the substrate 116. The semiconductor dies 118 embedded in or attached to the substrate 116 may also include a low-side power transistor die LS1 electrically connected between the switch node pad 128 and ground. In FIG. 3, the Vin and ground inputs are provided at the bottom side of the substrate 116.

According to this embodiment, the inductor 110 is positioned above at least part of the low-side power transistor die LS1, e.g., as shown in FIGS. 1 and 2. The metallic body 112 of the inductor module 100 is connected to a heat dissipation pad 130 included in the uppermost layer 124 of the substrate 116. The heat dissipation pad 130 is grounded, floating or at any voltage potential (e.g., Vin) but the output voltage potential Vout. Accordingly, the metallic body 112 of the inductor module 100 does not carry any of the current being switched by the high-side power transistor die HS1 and the low-side power transistor die LS1 at the switch node pad 128 of the substrate 116. In addition to enhancing thermal performance, the metallic body 112 of the inductor module 100 may be used as an additional electrical connection, e.g., a signal, ground, Vin or Vout current path going from top-to-bottom or vice-versa.

Further according to the embodiment illustrated in FIGS. 1 through 3, both the heat dissipation pad 130 of the substrate 116 and the metallic body 112 of the inductor module 100 are positioned above at least part of the high-side power transistor die HS1 and a driver die D1 for the low-side power transistor die LS1 and the high-side power transistor die HS1. The driver die D1 provides gate drive signals to the low-side power transistor die LS1 and the high-side power transistor die HS1.

For a multi-phase implementation where more than one phase current is switched, the semiconductor dies 118 embedded in or attached to the substrate 116 may also include a second high-side power transistor die HS2 electrically connected between the input voltage potential Vin of the power stage module 114 and a second switch node pad 132 included in the uppermost layer 124 of the substrate 116. The semiconductor dies 118 embedded in or attached to the substrate 116 may also include a second low-side power transistor die LS2 electrically connected between the second switch node pad 132 and ground.

According to this embodiment, the inductor module 100 may include a second inductor 136 to support the second phase. The second inductor 136 is positioned above at least part of the second low-side power transistor die LS2, e.g., as shown in FIGS. 1 and 2. The metallic body 112 of the inductor module 100 is connected to an additional heat dissipation pad 134 included in the uppermost layer 124 of the substrate 116. The metallic body 112 and the additional inductor 136 are electrically isolated from one another and the additional heat dissipation pad 130 is grounded, floating or at any voltage potential (e.g., Vin) but the output voltage potential Vout. Accordingly, the metallic body 112 of the inductor module 100 does not carry any of the phase current being switched by the second high-side power transistor die HS2 and the second low-side power transistor die LS2 at the second switch node pad 132 of the substrate 116. Both the second heat dissipation pad 130 of the substrate 116 and the metallic body 112 of the inductor module 100 are positioned above at least part of the second high-side power transistor die HS2 and a driver die D2 for the second low-side power transistor die LS2 and the second high-side power transistor die HS2. The metallic body 112 of the inductor module 100 may be split into two separate sections, one for each phase of the power stage module. Separately or in combination, the substrate 116 may have a single heat dissipation pad instead of two separate heat dissipation pads 130, 134 for the multi-phase embodiment.

In each case, the substrate 116 includes a separate output pad 138, 140 for each phase supported by the power stage module 114. Each inductor 110, 136 of the inductor module 100 connects the respective switch node pad 128, 132 to the corresponding output pad 138, 140 of the substrate 116. The input (Vin) and output (Vout) connections to the power stage module 114 may be made at the opposite side (e.g., the bottom) of the substrate 116 as the inductor module 100, e.g., as shown in FIGS. 1 through 3, or at the same side to which the inductor module 100 is mounted.

Also in FIGS. 1 through 3, the metallic body 112 of the inductor module 100 includes a first part 142 that partly covers the first main surface 104 of the magnetic core 102, a second part 144 that partly covers the second main surface 106 of the magnetic core 102, and a third part 146 that at least partly covers a first side face 108_1 of the magnetic core 102. In one embodiment, the first part 142, the second part 144 and the third part 146 of the metallic body 112 are integrally formed.

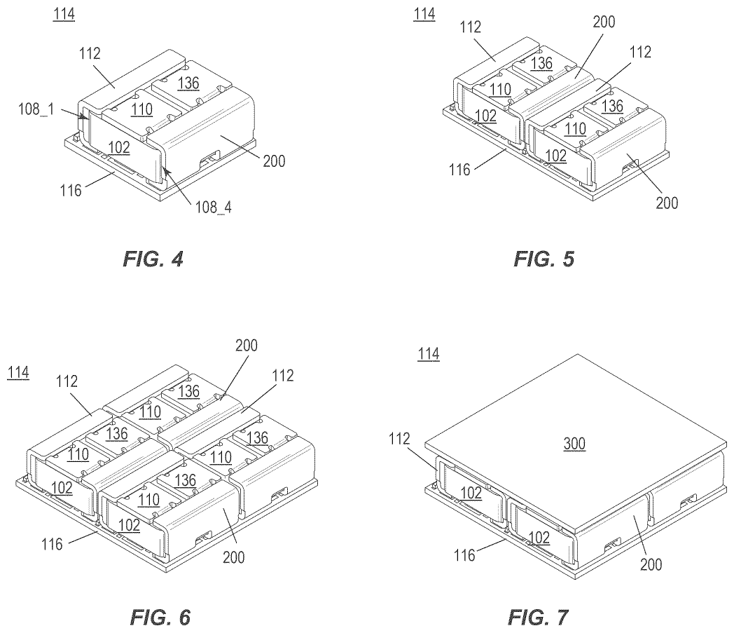

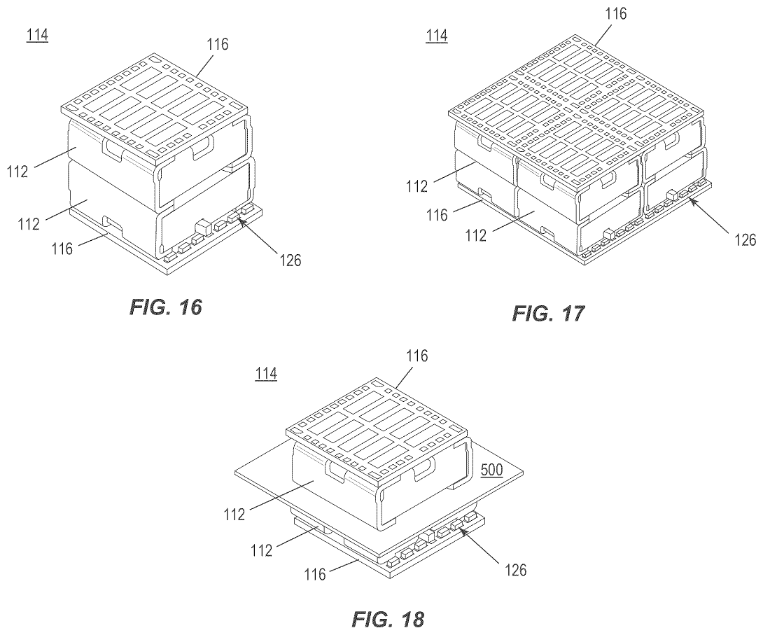

FIGS. 4 through 18 illustrate top perspective views of the inductor module 100, according to additional embodiments. In these embodiments, each metallic body included in the inductor module 100 to enhance thermal performance of the power stage module 114 may have surface features such as ridges, fins, etc., may be chemically treated to form surface features, may have channels formed therein to enable liquid cooling, and/or may have different thicknesses to further enhance thermal performance.

In FIG. 4, the metallic body 112 of the inductor module 100 adjoins a first side face 108_1 of the magnetic core 102 and the inductor module 100 includes an additional metallic body 200. The additional metallic body 200 adjoins the first main surface 104, the second main surface 106 and a side face 108_4 of the magnetic core 102 opposite the first side face 108_1. The additional metallic body 200 and each inductor 110, 136 are electrically isolated from one another. In one embodiment, the additional metallic body 200 is C-shaped and adjoins a single side face 108_4 of the magnetic core 102 opposite the first metallic body 112.

In FIG. 5, the power stage module 114 supports four (4) individual current phases. In this embodiment, two (2) of the inductor modules 100 shown in FIG. 4 are attached to the substrate 116 of the power stage module 114, with each inductor 110, 136 of each inductor module 100 supporting an individual phase of the system. Each inductor module 100 may include two metallic bodies 112, 200 adjoining opposite side faces 108_1, 108_4 of the magnetic core 102 as shown in FIG. 5, or a single metallic body 112 adjoining one side face 108_1 of the magnetic core 102 as shown in FIGS. 1-3.

In FIG. 6, the power stage module 114 supports eight (8) individual current phases. In this embodiment, each inductor module 100 mounted to the substrate 116 of the power stage module 114 may support four (4) individual phases of the system. Each inductor module 100 may include two metallic bodies 112, 200 adjoining opposite side faces 108_1, 108_4 of the magnetic core 102 as shown in FIG. 6, or a single metallic body 112 adjoining one side face 108_1 of the magnetic core 102 as shown in FIGS. 1-3. Each individual inductor module 100 instead may support a different number of phases than four (4), e.g., one (1), two (2), three (3), etc.

In FIG. 7, a cooling plate 300 is attached to the topside of the inductor modules 100. The cooling plate 300 may be electrically insulative so that the phases are not shorted together. The cooling plate 300 instead may be may of an electrically conductive material such as a metal or metal alloy, with the phase isolation being provided by other means.

The embodiment illustrated in FIG. 8 is similar to the embodiment illustrated in FIG. 5, but instead with the two (2) inductor modules 100 being vertically stacked on one another with the respective substrates 116 facing away from one another. As such, each inductor module 100 is mounted to a separate substrate 116 in FIG. 8, whereas a single substrate 116 is used in FIG. 5 to accommodate both inductor modules 100.

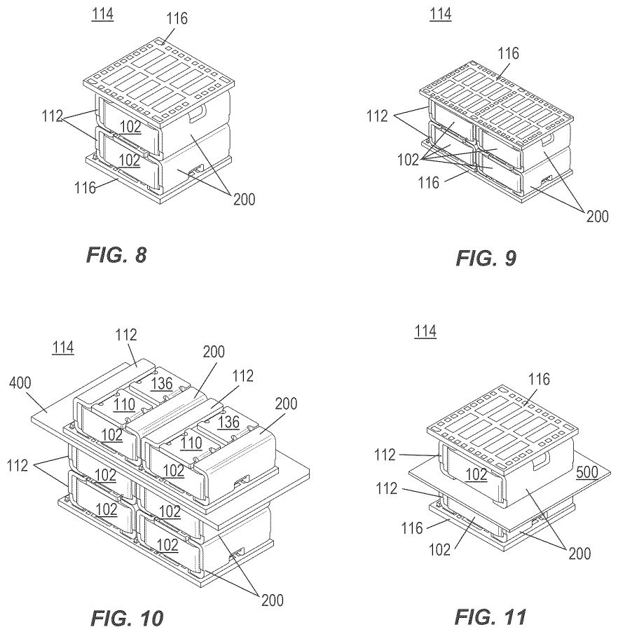

The embodiment illustrated in FIG. 9 expands upon the embodiment illustrated in FIG. 8, by including two (2) additional inductor modules 100 between the upper and lower substrates 116, thereby supporting more phases.

The embodiment illustrated in FIG. 10 expands upon the embodiment illustrated in FIG. 9, by including an interposer 400 between the upper substrate 116 and the lower four (4) inductor modules 100. Two (2) or more further inductor modules 100 may be attached to an additional substrate 116 which is mounted to the topside of the interposer 400. Still other lateral and/or vertical stacking configurations are contemplated to support more current phases.

The embodiment illustrated in FIG. 11 is similar to the embodiment illustrated in FIG. 8, but with a cooling plate 500 vertically interposed between the two (2) inductor modules 100. The cooling plate 500 may have the same or different properties as the cooling plate 300 shown in FIG. 7.

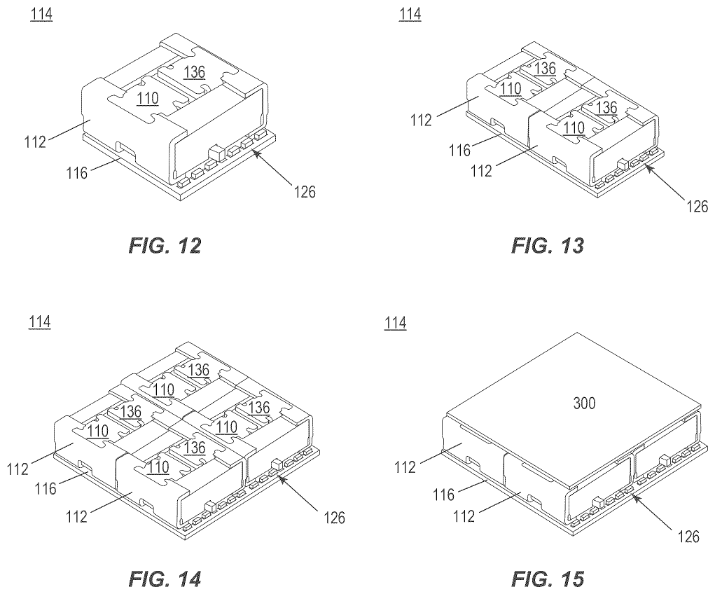

FIGS. 12 through 18 illustrate embodiments that are similar to the embodiments shown in FIGS. 4 through 9 and 11, respectively, but with the metallic body 112 of each inductor module 100 adjoining each side face 108 of the corresponding magnetic core 102. That is, the metallic body 112 adjoins all four (4) side faces 108 of the corresponding magnetic core 102. Each metallic body may be formed as a single, integral unit or from two (2) or more parts that are affixed to the corresponding magnetic core 102.

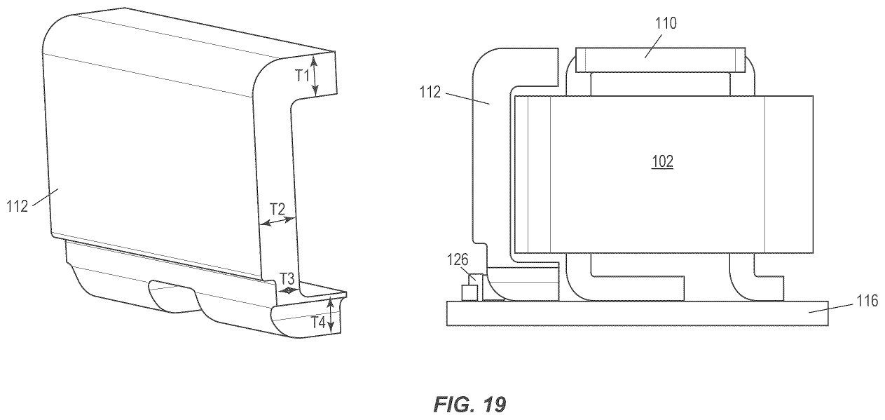

FIG. 19 illustrates a side view of the inductor module 100 and a side perspective view of the metallic body 112 included in the inductor module 100, according to another embodiment. In FIG. 19, the metallic body 112 is formed by metal injection molding or metal 3D printing. This enables the metallic body 112 to have enhanced surface features such as ridges, fins, etc., channels to enable liquid cooling, and/or different thicknesses (e.g., T1, T2, T3, T4 in FIG. 19).

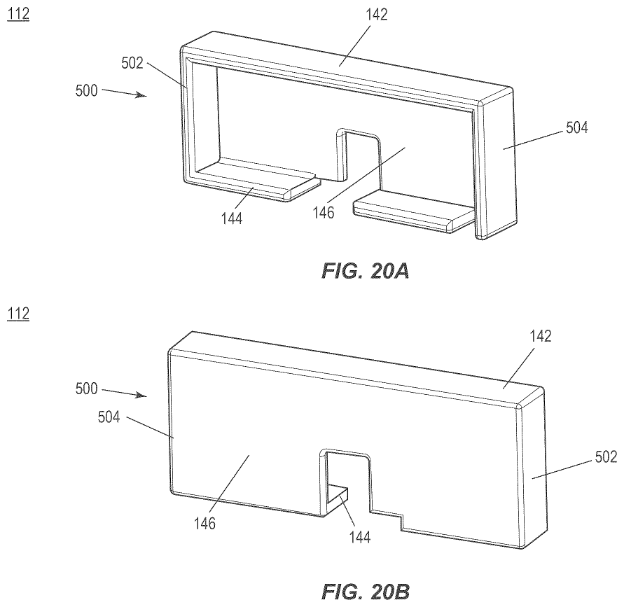

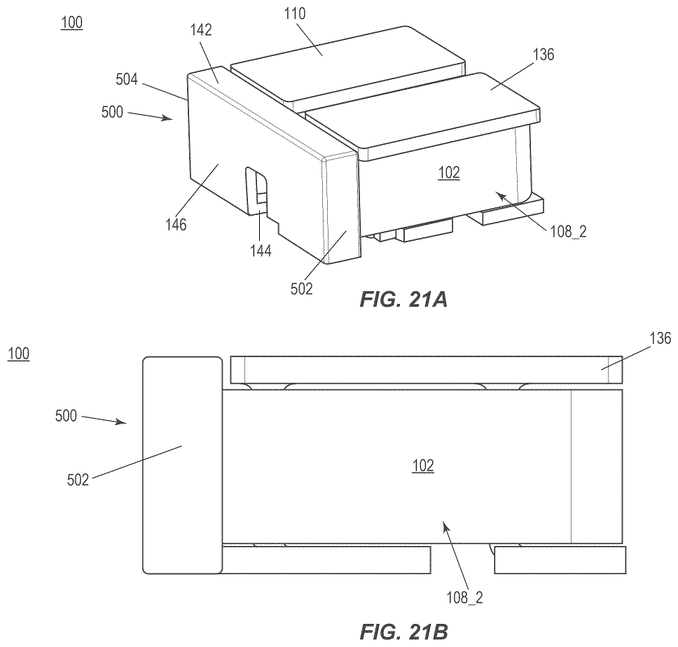

FIGS. 20A and 20B illustrates opposing side perspective views of the metallic body 112 included in the inductor module 100, according to another embodiment. As shown in FIGS. 20A and 20B, the metallic body 112 is formed as a cap 500 that is placed on an end of the magnetic core 102. FIG. 21A shows a side perspective view of the inductor module 100 with the metallic body cap 500 placed on an end of the magnetic core 102. FIG. 21B shows a corresponding side view of the inductor module 100 with the metallic body cap 500 in place.

According to this embodiment, the metallic body 112 further includes a fourth part 502 that at least partly covers a second side face 108_2 of the magnetic core 102 that adjoins the first side face 108_1 and a fifth part 504 that at least partly covers a third side face 108_3 of the magnetic core 102 that is opposite the second side face 108_2. The first part 142, the second part 144, the third part 146, the fourth part 502, and the fifth part 504 may be integrally formed or may be implemented as individual sections that are each affixed to the magnetic core 102.

Although the present disclosure is not so limited, the following numbered examples demonstrate one or more aspects of the disclosure.

Example 1. An inductor module, comprising: a magnetic core having a first main surface, a second main surface opposite the first main surface, and a plurality of side faces extending between the first and the second main surfaces; an inductor extending from the first main surface to the second main surface through the magnetic core; and a metallic body adjoining the first main surface, the second main surface and at least one of the side faces of the magnetic core, wherein the metallic body and the inductor are electrically isolated from one another.

Example 2. The inductor module of example 1, wherein the metallic body is C-shaped and adjoins a single side face of the magnetic core.

Example 3. The inductor module of example 1, wherein the metallic body adjoins two or more side faces of the magnetic core.

Example 4. The inductor module of any of examples 1 through 3, wherein the metallic body is a cap placed on an end of the magnetic core.

Example 5. The inductor module of any of examples 1 through 4, wherein the metallic body comprises: a first part that partly covers the first main surface of the magnetic core; a second part that partly covers the second main surface of the magnetic core; and a third part that at least partly covers a first side face of the magnetic core, wherein the first part, the second part and the third part are integrally formed.

Example 6. The inductor module of example 5, wherein the metallic body further comprises: a fourth part that at least partly covers a second side face of the magnetic core that adjoins the first side face; and a fifth part that at least partly covers a third side face of the magnetic core that is opposite the second side face, wherein the first part, the second part, the third part, the fourth part, and the fifth part are integrally formed.

Example 7. The inductor module of any of examples 1 through 6, wherein the metallic body adjoins a first side face of the magnetic core.

Example 8. The inductor module of example 7, further comprising: an additional metallic body adjoining the first main surface, the second main surface and a second side face of the magnetic core opposite the first side face, wherein the additional metallic body and the inductor are electrically isolated from one another.

Example 9. The inductor module of any of examples 1 and 3 through 7, wherein the metallic body adjoins each side face of the magnetic core.

Example 10. A method of producing an inductor module, the method comprising: partly embedding an inductor in a magnetic core having a first main surface, a second main surface opposite the first main surface, and a plurality of side faces extending between the first and the second main surfaces, such that the inductor extends from the first main surface to the second main surface through the magnetic core; and fixing a metallic body to the magnetic core, the metallic body adjoining the first main surface, the second main surface and at least one of the side faces of the magnetic core, wherein the metallic body and the inductor are electrically isolated from one another.

Example 11. A power stage module, comprising: a substrate; a plurality of semiconductor dies attached to or embedded in the substrate; and an inductor module mounted to a first side of the substrate above the semiconductor dies, wherein the inductor module comprises: a magnetic core having a first main surface that faces the substrate, a second main surface opposite the first main surface, and a plurality of side faces extending between the first and the second main surfaces; an inductor partly embedded in the magnetic core and electrically connecting a switch node pad at the first side of the substrate to an output pad at the first side of the substrate; and a metallic body adjoining the first main surface, the second main surface and at least one of the side faces of the magnetic core, the metallic body being connected to a heat dissipation pad at the first side of the substrate, wherein the heat dissipation pad is grounded, floating or at any voltage potential but output voltage potential.

Example 12. The power stage module of example 11, wherein the plurality of semiconductor dies includes a high-side power transistor die electrically connected between the input voltage potential and the switch node pad and a low-side power transistor die electrically connected between the switch node pad and ground, wherein the inductor is positioned above at least part of the low-side power transistor die, and wherein both the heat dissipation pad and the metallic body are positioned above at least part of the high-side power transistor die and a driver die for the low-side power transistor die and the high-side power transistor die.

Example 13. The power stage module of example 11 or 12, wherein the metallic body is C-shaped and adjoins a single side face of the magnetic core.

Example 14. The power stage module of example 11 or 12, wherein the metallic body adjoins two or more side faces of the magnetic core.

Example 15. The power stage module of any of examples 11 through 14, wherein the metallic body is a cap placed on an end of the magnetic core.

Example 16. The power stage module of any of examples 11 through 15, wherein the metallic body comprises: a first part that partly covers the first main surface of the magnetic core; a second part that partly covers the second main surface of the magnetic core; and a third part that at least partly covers a first side face of the magnetic core, wherein the first part, the second part and the third part are integrally formed.

Example 17. The power stage module of example 16, wherein the metallic body further comprises: a fourth part that at least partly covers a second side face of the magnetic core that adjoins the first side face; and a fifth part that at least partly covers a third side face of the magnetic core that is opposite the second side face, wherein the first part, the second part, the third part, the fourth part, and the fifth part are integrally formed.

Example 18. The power stage module of any of examples 11 through 17, wherein the metallic body adjoins a first side face of the magnetic core.

Example 19. The power stage module of example 18, further comprising: an additional metallic body adjoining the first main surface, the second main surface and a second side face of the magnetic core opposite the first side face, wherein the additional metallic body and the inductor are electrically isolated from one another.

Example 20. The power stage module of any of examples 11, 12 and 14 through 19, wherein the metallic body adjoins each side face of the magnetic core.

Example 21. A method of producing a power stage module, the method comprising: attaching a plurality of semiconductor dies to a substrate or embedding the plurality of semiconductor dies in the substrate; and mounting an inductor module to a first side of the substrate above the semiconductor dies, the inductor module comprising: a magnetic core having a first main surface that faces the substrate, a second main surface opposite the first main surface, and a plurality of side faces extending between the first and the second main surfaces; an inductor partly embedded in the magnetic core and electrically connecting a switch node pad at the first side of the substrate to an output pad at the first side of the substrate; and a metallic body adjoining the first main surface, the second main surface and at least one of the side faces of the magnetic core, the metallic body being connected to a heat dissipation pad at the first side of the substrate, wherein the heat dissipation pad is grounded, floating or at any voltage potential but output voltage potential.

Terms such as “first”, “second”, and the like, are used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to include all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An inductor module, comprising:
a magnetic core having a first main surface, a second main surface opposite the first main surface, and a plurality of side faces extending between the first and the second main surfaces;
an inductor extending from the first main surface to the second main surface through the magnetic core; and
a metallic body adjoining the first main surface, the second main surface and at least one of the side faces of the magnetic core,
wherein the metallic body and the inductor are electrically isolated from one another.

2. The inductor module of claim 1, wherein the metallic body is C-shaped and adjoins a single side face of the magnetic core.

3. The inductor module of claim 1, wherein the metallic body adjoins two or more side faces of the magnetic core.

4. The inductor module of claim 1, wherein the metallic body is a cap placed on an end of the magnetic core.

5. The inductor module of claim 1, wherein the metallic body comprises:
a first part that partly covers the first main surface of the magnetic core;
a second part that partly covers the second main surface of the magnetic core; and
a third part that at least partly covers a first side face of the magnetic core,
wherein the first part, the second part and the third part are integrally formed.

6. The inductor module of claim 5, wherein the metallic body further comprises:
a fourth part that at least partly covers a second side face of the magnetic core that adjoins the first side face; and
a fifth part that at least partly covers a third side face of the magnetic core that is opposite the second side face,
wherein the first part, the second part, the third part, the fourth part, and the fifth part are integrally formed.

7. The inductor module of claim 1, wherein the metallic body adjoins a first side face of the magnetic core.

8. The inductor module of claim 7, further comprising:
an additional metallic body adjoining the first main surface, the second main surface and a second side face of the magnetic core opposite the first side face,
wherein the additional metallic body and the inductor are electrically isolated from one another.

9. The inductor module of claim 1, wherein the metallic body adjoins each side face of the magnetic core.

10. A method of producing an inductor module, the method comprising:
partly embedding an inductor in a magnetic core having a first main surface, a second main surface opposite the first main surface, and a plurality of side faces extending between the first and the second main surfaces, such that the inductor extends from the first main surface to the second main surface through the magnetic core; and
fixing a metallic body to the magnetic core, the metallic body adjoining the first main surface, the second main surface and at least one of the side faces of the magnetic core,
wherein the metallic body and the inductor are electrically isolated from one another.

11. A power stage module, comprising:
a substrate;
a plurality of semiconductor dies attached to or embedded in the substrate; and
an inductor module mounted to a first side of the substrate above the semiconductor dies,
wherein the inductor module comprises:
a magnetic core having a first main surface that faces the substrate, a second main surface opposite the first main surface, and a plurality of side faces extending between the first and the second main surfaces;
an inductor partly embedded in the magnetic core and electrically connecting a switch node pad at the first side of the substrate to an output pad at the first side of the substrate; and
a metallic body adjoining the first main surface, the second main surface and at least one of the side faces of the magnetic core, the metallic body being connected to a heat dissipation pad at the first side of the substrate,
wherein the heat dissipation pad is grounded, floating or at any voltage potential but output voltage potential.

12. The power stage module of claim 11, wherein the plurality of semiconductor dies includes a high-side power transistor die electrically connected between the input voltage potential and the switch node pad and a low-side power transistor die electrically connected between the switch node pad and ground, wherein the inductor is positioned above at least part of the low-side power transistor die, and wherein both the heat dissipation pad and the metallic body are positioned above at least part of the high-side power transistor die and a driver die for the low-side power transistor die and the high-side power transistor die.

13. The power stage module of claim 11, wherein the metallic body is C-shaped and adjoins a single side face of the magnetic core.

14. The power stage module of claim 11, wherein the metallic body adjoins two or more side faces of the magnetic core.

15. The power stage module of claim 11, wherein the metallic body is a cap placed on an end of the magnetic core.

16. The power stage module of claim 11, wherein the metallic body comprises:
a first part that partly covers the first main surface of the magnetic core;
a second part that partly covers the second main surface of the magnetic core; and
a third part that at least partly covers a first side face of the magnetic core,
wherein the first part, the second part and the third part are integrally formed.

17. The power stage module of claim 16, wherein the metallic body further comprises:
a fourth part that at least partly covers a second side face of the magnetic core that adjoins the first side face; and
a fifth part that at least partly covers a third side face of the magnetic core that is opposite the second side face,
wherein the first part, the second part, the third part, the fourth part, and the fifth part are integrally formed.

18. The power stage module of claim 11, wherein the metallic body adjoins a first side face of the magnetic core.

19. The power stage module of claim 18, further comprising:
an additional metallic body adjoining the first main surface, the second main surface and a second side face of the magnetic core opposite the first side face,
wherein the additional metallic body and the inductor are electrically isolated from one another.

20. The power stage module of claim 11, wherein the metallic body adjoins each side face of the magnetic core.

21. A method of producing a power stage module, the method comprising:
attaching a plurality of semiconductor dies to a substrate or embedding the plurality of semiconductor dies in the substrate; and
mounting an inductor module to a first side of the substrate above the semiconductor dies, the inductor module comprising:
a magnetic core having a first main surface that faces the substrate, a second main surface opposite the first main surface, and a plurality of side faces extending between the first and the second main surfaces;
an inductor partly embedded in the magnetic core and electrically connecting a switch node pad at the first side of the substrate to an output pad at the first side of the substrate; and
a metallic body adjoining the first main surface, the second main surface and at least one of the side faces of the magnetic core, the metallic body being connected to a heat dissipation pad at the first side of the substrate,
wherein the heat dissipation pad is grounded, floating or at any voltage potential but output voltage potential.
